(19) United States
(12) Patent Application Publication
(10) Pub. No.: US 2026/0123228 A1
(43) Pub. Date: Apr. 30, 2026

(54) DISPLAY DEVICE

(71) Applicant: LG Display Co., Ltd., Seoul (KR)

(72) Inventors: HoonSok SON, Paju-si (KR); KiSoub YANG, Paju-si (KR); Jaehwan MYUNG, Paju-si (KR)

(73) Assignee: LG Display Co., Ltd., Seoul (KR)

(21) Appl. No.: 19/248,148

(22) Filed: Jun. 24, 2025

(30) Foreign Application Priority Data
Oct. 31, 2024 (KR) 10-2024-0152281

(51) Int. Cl. H10K 59/38; H10K 59/122; H10K 59/80

(52) U.S. Cl. CPC H10K 59/38; H10K 59/122; H10K 59/879

(57) ABSTRACT

Embodiments of the disclosure relate to a display device with a structure for protecting a color filter layer. The display device may include a substrate, a light emitting layer on the substrate, an encapsulation layer on the light emitting layer. A first color filter may be on the encapsulation layer, and a first protective layer may overlap the first color filter. A first protective layer may overlap the first color filter. The first protective layer may extend from an upper surface of the first color filter to a side surface of the first color filter and may further extend to the upper surface of the encapsulation layer. This structure may reduce damage to the color filter during subsequent fabrication processes. The protective layer may comprise a transparent, nonconductive material that enhances optical performance and enables a flat surface for integration of additional optical components such as a microlens array.

### CROSS-REFERENCE TO RELATED APPLICATION

This application claims priority from Korean Patent Application No. 10-2024-0152281, filed on Oct. 31, 2024, which is hereby incorporated by reference for all purposes as if fully set forth herein.

### BACKGROUND

### Technical Field

Embodiments of the disclosure relate to display devices.

### Description of Related Art

As the information society develops, demand for display devices for displaying images is increasing in various forms. Various display devices, such as liquid crystal display devices and organic light emitting display devices, are being utilized in recent years.

The display device may include an encapsulation layer and a color filter layer. The encapsulation layer may be a layer that protects the light emitting element. The color filter layer may change the light from the light emitting element into a specific color.

### BRIEF SUMMARY

When the color filter layer is formed, the color filter layer may be damaged. The disclosed display device includes a protective layer structure that prevents damage to color filters during the sequential fabrication process. A first protective layer made of a transparent and non-conductive metal oxide covers a first color filter and extends to the encapsulation layer, protecting the first filter when adjacent filters are formed. A second protective layer similarly covers a second color filter and overlaps the first protective layer, helping to maintain a flat and uniform color filter surface. This arrangement supports accurate placement of a micro-lens array and improves both luminance and power efficiency.

Metal partition walls are placed between adjacent color filters to define boundaries and reflect light toward the center of each micro-lens. These partition walls also work with the protective layers to prevent physical or chemical damage during manufacturing. The combined effect of these features supports higher optical performance and stable panel quality, especially in display devices using fine pixel structures such as OLED on silicon.

Embodiments of the disclosure may provide a display device capable of protecting a color filter layer through a protective layer.

Embodiments of the disclosure may provide a display device capable of placing a color filter layer flat through a protective layer.

Embodiments of the disclosure may provide a display device capable of placing a micro-lens array flat through a protective layer.

Embodiments of the disclosure may provide a display device capable of low power consumption by increasing power efficiency by placing a color filter layer and a micro-lens array flat.

Embodiments of the disclosure may provide a display device comprising a substrate, a light emitting element layer disposed on the substrate, an encapsulation layer disposed on the light emitting element layer, a first color filter disposed on the encapsulation layer, and a first protective layer extending from a first color filter upper surface of the first color filter to a first color filter side surface of the first color filter and extending from the first color filter side surface to an encapsulation layer upper surface of the encapsulation layer.

The display device may further comprise a second color filter positioned outside the first color filter side surface and positioned on the encapsulation layer. The first protective layer may pass through a lower portion of the second color filter.

The first protective layer may include a transparent material. The first protective layer may be a non-conductive metal oxide film.

The first protective layer may be disposed to cover the first color filter. The display device may further comprise a second color filter positioned outside the first color filter side surface and formed after the first protective layer covering the first color filter is formed.

The display device may further comprise a second protective layer positioned on a second color filter upper surface of the second color filter. The second protective layer may extend from the second color filter upper surface to a position where the first protective layer overlaps the first color filter. The second protective layer may extend from the second color filter upper surface to a second color filter side surface of the second color filter and extend from the second color filter side surface to below the second color filter to contact the first protective layer.

Embodiments of the disclosure may provide a display device comprising a substrate, a light emitting element layer disposed on the substrate, an encapsulation layer disposed on the light emitting element layer, a plurality of partition walls disposed on the encapsulation layer and extending in a first direction, a first color filter disposed on the encapsulation layer and positioned between at least two of the plurality of partition walls, and a first protective layer covering an upper surface of the first color filter, wherein a side surface of the first color filter is disposed to contact the plurality of partition walls or the first protective layer, and wherein the plurality of partition walls include a material included in the first protective layer.

According to embodiments of the disclosure, there may be provided a display device capable of protecting a color filter layer through a protective layer.

According to embodiments of the disclosure, there may be provided a display device capable of placing a color filter layer flat through a protective layer.

According to embodiments of the disclosure, there may be provided a display device capable of placing a micro-lens array flat through a protective layer.

According to embodiments of the disclosure, there may be provided a display device capable of low power consumption by increasing power efficiency by placing a color filter layer and a micro-lens array flat.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is a view illustrating a subpixel according to embodiments of the disclosure;

FIG. 3 is a plan view illustrating a plurality of subpixels according to embodiments of the disclosure;

FIG. 4 is a schematic cross-sectional view taken along area A-B of FIG. 3;

FIG. 5 is an example cross-sectional view taken along area A-B of FIG. 3;

FIG. 6 is an example cross-sectional view taken along area A-B of FIG. 3;

FIG. 7 is an example cross-sectional view taken along area A-B of FIG. 3; and

FIG. 8 is a plan view illustrating a plurality of subpixels according to embodiments of the disclosure.

### DETAILED DESCRIPTION

Hereinafter, embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked” “, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the disclosure are described in detail with reference to the accompanying drawings.

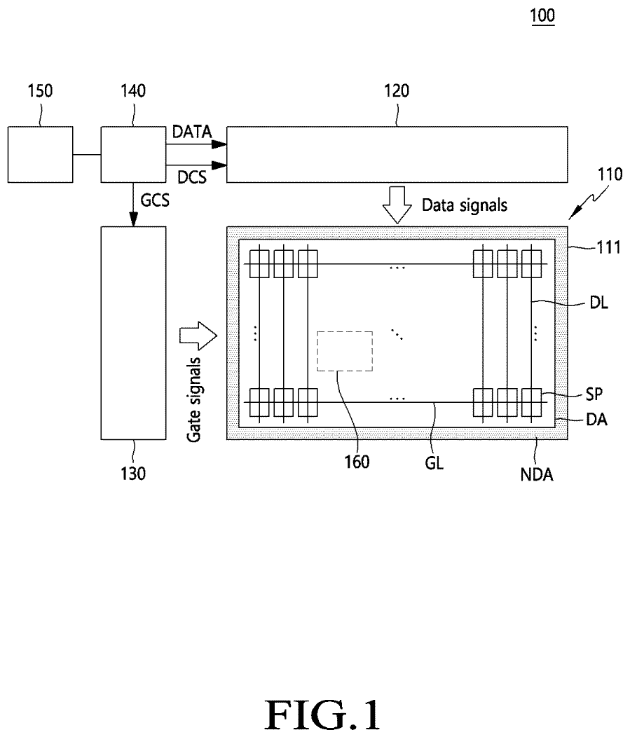

FIG. 1 is a view illustrating a system configuration of a display device 100 according to embodiments of the disclosure.

Referring to FIG. 1, a display device 100 according to embodiments of the disclosure may include a display panel 110 and display driving circuits, as components for displaying images. The display driving circuits are circuits for driving the display panel 110 and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA positioned outside the display area DA.

A plurality of subpixels SP for image displaying may be disposed in the display area DA, and the non-display area NDA may include a pad area PA positioned in a first direction from the display area DA.

In the display panel 110 according to embodiments of the disclosure, the non-display area NDA may be very small. In the disclosure, the non-display area NDA is also referred to as a “bezel.”

For example, the non-display area NDA may include a first non-display area positioned outside the display area DA in a first direction, a second non-display area positioned outside the display area DA in a second direction crossing the first direction, a third non-display area positioned outside the display area DA in a direction opposite to the first direction, and a fourth non-display area positioned outside the display area DA in a direction opposite to the second direction. One or two of the first to fourth non-display areas may include a pad area where the data driving circuit 120 is connected or bonded. Two or three of the first to fourth non-display areas where the pad area is not included may be very small.

As another example, the boundary area between the display area DA and the non-display area NDA may be bent so that the non-display area NDA may be positioned under the display area. In this case, no or little change may be made to the non-display area NDA shown to the user when the user views the display area 100 from the front.

Various types of signal lines for driving a plurality of subpixels SP may be disposed on the substrate 111 of the display panel 110.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the first direction. Each of the plurality of gate lines GL may be disposed to extend in the second direction. Here, the first direction may be a column direction and the second direction may be a row direction. The first direction may be the row direction, and the second direction may be the column direction. For convenience of description, described below is an example in which each of the plurality of data lines DL is disposed in the column direction, and each of the plurality of gate lines GL is disposed in the row direction.

The data driving circuit 120 is a circuit for driving the plurality of data lines DL, and may out data signals to the plurality of data lines DL.

The data driving circuit 120 may receive digital image data DATA from the display controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but alternatively, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the disclosure, the gate driving circuit 130 may be embedded, in a gate in panel (GIP) type, in the display panel 110. When the gate driving circuit 130 is of the gate in panel type, the gate driving circuit 130 may be formed on the substrate 111 of the display panel 110 during the manufacturing process of the display panel 110.

In the display device 100 according to embodiments of the disclosure, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type may also be referred to as a “gate-in-panel circuit.”

The display controller 140 is a device for controlling the data driving circuit 120 and the gate driving circuit 130 and may control driving timings for the plurality of data lines DL and driving timings for the plurality of gate lines GL.

The display controller 140 may supply a data driving control signal DCS to the data driving circuit 120 to control the data driving circuit 120 and may supply a gate driving control signal GCS to the gate driving circuit 130 to control the gate driving circuit 130.

The display controller 140 may receive input image data from the host system 150 and supply image data DATA to the data driving circuit 120 based on the input image data.

The display controller 140 may be implemented as a separate component from the data driving circuit 120, or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor.

The display controller 140 may be mounted on a printed circuit board or a flexible printed circuit and may be electrically connected with the data driving circuit 120 and the gate driving circuit 130 through the printed circuit board or the flexible printed circuit.

The display controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

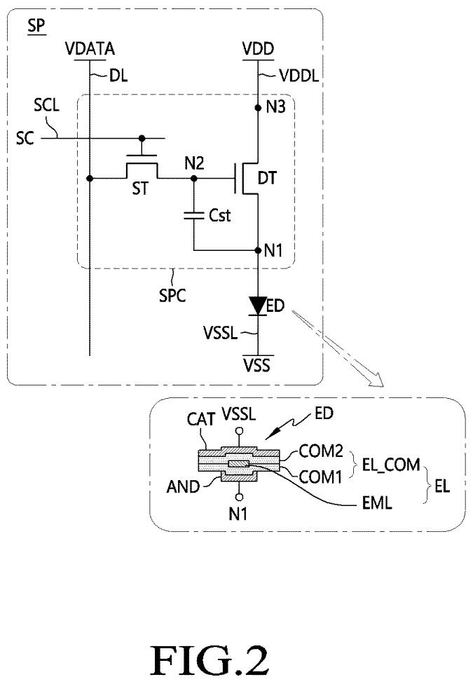

FIG. 2 is a view illustrating a subpixel SP according to embodiments of the disclosure.

Referring to FIG. 2, each of the plurality of subpixels SP may include a light emitting element ED and a subpixel circuit unit SPC for driving the light emitting element ED.

Referring to FIG. 2, the subpixel circuit SPC may include a plurality of pixel driving transistors and at least one capacitor for driving the light emitting element ED. In the disclosure, the subpixel circuit SPC may drive the light emitting element ED by supplying a driving current to the light emitting element ED at a predetermined timing. The light emitting element ED may be driven by a driving current to emit light.

The plurality of pixel driving transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common pixel driving voltage including the driving voltage VDD and the base voltage VSS may be applied to the subpixel SP.

The light emitting element ED may include an anode AND, a light emitting element intermediate layer EL, and a cathode CAT. The light emitting element intermediate layer EL may be disposed between the anode AND and the cathode CAT.

When the light emitting element ED is an organic light emitting element, the light emitting element intermediate layer EL may include a light emitting layer EML, a first common intermediate layer COM1 between the anode AND and the light emitting layer EML, and a second common intermediate layer COM2 between the light emitting layer EML and the cathode. The light emitting layer EML may be disposed for each subpixel SP. In contrast, the first common intermediate layer COM1 and the second common intermediate layer COM2 may be commonly disposed over a plurality of subpixels SP. The light emitting layer EML may be disposed for each light emitting area, and the first common intermediate layer COM1 and the second common intermediate layer COM2 may be commonly disposed over the plurality of light emitting areas and the non-light emitting area. The first common intermediate layer COM1 and the second common intermediate layer COM2 may be collectively referred to as a common intermediate layer EL_COM.

For example, the first common intermediate layer COM1 may include a hole injection layer HIL and a hole transport layer HTL. The second common intermediate layer COM2 may include an electron transport layer ETL and an electron injection layer EIL. The hole injection layer may inject holes from the anode AND to the hole transport layer, the hole transport layer may transport the holes to the light emitting layer EML, the electron injection layer may inject electrons from the cathode CAT to the electron transport layer, and the electron transport layer may transport electrons to the light emitting layer EML.

For example, the cathode CAT may be electrically connected to the base voltage line VSSL. The base voltage VSS, which is one type of the common pixel driving voltage, may be applied to the cathode CAT through the base voltage line VSSL. The anode AND may be electrically connected to the first node N1 of the driving transistor DT of each subpixel SP. In the disclosure, “the base voltage VSS” may also be referred to as a “low potential power voltage VSS”, and “the base voltage line VSSL” may also be referred to as a “low potential power voltage line VSSL”.

For example, the anode AND may be a pixel electrode disposed in each subpixel SP, and the cathode CAT may be a common electrode commonly disposed in a plurality of subpixels SP. As another example, the cathode CAT may be a pixel electrode disposed in each subpixel SP, and the anode AND may be a common electrode commonly disposed in a plurality of subpixels SP. Hereinafter, for convenience of description, it is assumed that the anode AND is a pixel electrode and the cathode CAT is a common electrode.

Each light emitting element ED may include portions in which the anode AND, the light emitting element intermediate layer EL, and the cathode CAT overlap each other. A predetermined light emitting area may be formed by each light emitting element ED. For example, the emission area of each light emitting element ED may include an area in which the anode AND, the light emitting element intermediate layer EL, and the cathode CAT overlap.

For example, the light emitting element ED may be an organic light emitting diode (OLED), an inorganic light emitting diode (LED), or a quantum dot light emitting element. For example, when the light emitting element ED is an organic light emitting diode (OLED), the light emitting element intermediate layer EL of the light emitting element ED may include a light emitting element intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node N1 electrically connected to the light emitting element ED, a second node N2 to which the data signal VDATA may be applied, and a third node N3 to which the driving voltage VDD is applied from the driving voltage line VDDL.

In the driving transistor DT, the second node N2 may be a gate node, the first node N1 may be a source node or a drain node, and the third node N3 may be a drain node or a source node. Hereinafter, for convenience of description, in the driving transistor DT, the second node N2 may be a gate node, the first node N1 may be a source node, and the third node N3 may be a drain node.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. In contrast, when the display panel 110 has a bottom emission structure, the subpixel circuit SPC may not overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor.

Depending on the structure of the subpixel circuit SPC, the type and number of gate lines or the gate signals supplied to the subpixel SP may vary.

Further, the type and the number of common pixel driving voltages supplied to the subpixel SP may vary according to the structure of the subpixel circuit SPC.

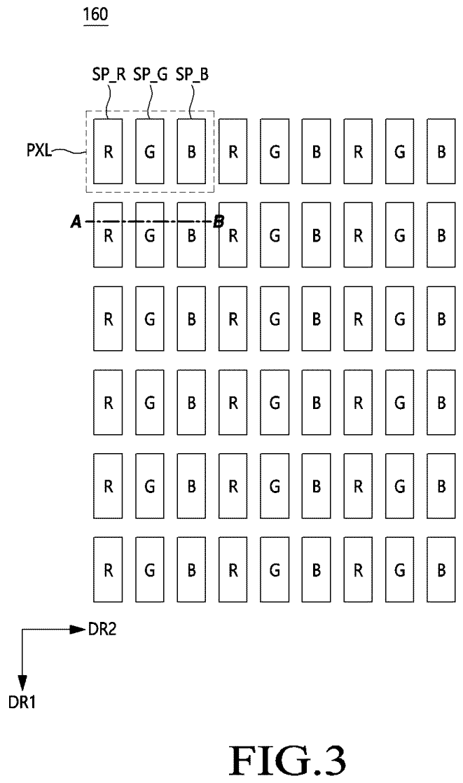

FIG. 3 is a plan view illustrating a plurality of subpixels SP according to embodiments of the disclosure.

Referring to FIG. 3, an enlarged view of a partial area 160 of the display panel 110 of FIG. 1 may be identified.

Referring to FIG. 3, a plurality of subpixels SP may be disposed in a matrix form.

The plurality of subpixels SP may include a red subpixel SP_R, a green subpixel SP_G, and a blue subpixel SP_B. The red subpixel SP_R, the green subpixel SP_G, and the blue subpixel SP_B may form one pixel PXL.

The subpixels SP that display the same color among the plurality of subpixels SP may be disposed in a line in a first direction DR1.

Referring to FIG. 3, subpixels SP having the same color may be disposed in the first direction DR1. Referring to FIG. 3, it may be identified that red subpixels SP_R are disposed in a line in the first direction DR1 in the first, fourth, and seventh columns. It may be identified that the green subpixels SP_G are disposed in a line in the first direction DR1 in the second, fifth, and eighth columns. It may be identified that the blue subpixels SP_B are disposed in a line in the first direction DR1 in the third, sixth, and ninth columns.

Referring to FIG. 3, subpixels SP of alternating colors may be disposed in the second direction DR2. For example, the plurality of subpixels SP may be disposed in the order of red, green, and blue. Referring to FIG. 3, a plurality of subpixels SP disposed in the order of red, green, blue, red, green, blue, red, green, and blue in the first row may be identified.

Referring to FIG. 3, area A-B may be identified. Hereinafter, a cross-sectional view illustrating the area A-B is described.

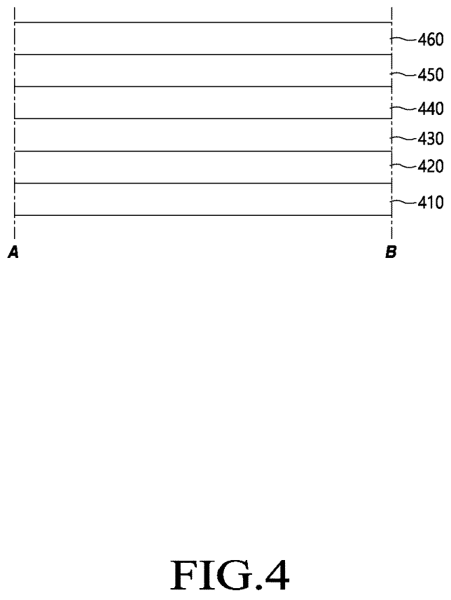

FIG. 4 is a schematic cross-sectional view taken along area A-B of FIG. 3.

Referring to FIG. 4, the display panel 110 may include a substrate 410, a transistor layer 420, a light emitting element layer 430, an encapsulation layer 440, a color filter layer 450, and a micro-lens array 460.

The substrate 410 may be disposed at the lowermost portion of the display panel 110. The substrate 410 may be a silicon wafer. When the substrate 410 is a silicon wafer, the display panel 110 may be manufactured using a semiconductor process.

The transistor layer 420 may be disposed on the substrate 410. The transistor layer 420 may be a layer in which a circuit for driving the light emitting element ED illustrated in FIG. 2 is disposed. The transistor layer 420 may be a layer in which the subpixel circuit SPC illustrated in FIG. 2 is disposed.

The light emitting element layer 430 may be disposed on the transistor layer 420. The light emitting element layer 430 may be a layer in which a light emitting element is disposed. The light emitting element disposed in the light emitting element layer 430 may be controlled by a subpixel circuit disposed in the transistor layer 420.

The encapsulation layer 440 may be disposed on the light emitting element layer 430. The encapsulation layer 440 may protect the light emitting element disposed in the light emitting element layer 430 from the outside. The encapsulation layer 440 may include an organic material or an inorganic material. Further, the encapsulation layer 440 may include a plurality of organic material layers and a plurality of inorganic material layers. For example, the encapsulation layer 440 may sequentially include an inorganic material layer, an organic material layer, and an inorganic material layer.

The color filter layer 450 may be disposed on the encapsulation layer 440. The color filter layer 450 may include a plurality of color filters. For example, the color filter layer 450 may include a red color filter R, a green color filter G, and a blue color filter B. Light incident on the color filter layer 450 may be changed into a specific color and emitted.

The micro-lens array 460 may be disposed on the color filter layer 450. The micro-lens array 460 may include a plurality of lenses. The plurality of lenses may collect light incident on the plurality of lenses in a center direction. For example, one lens may overlap one color filter. Light emitted through the color filter may pass through the lens, and light incident on the lens may be directed toward the center of one lens.

Hereinafter, a cross-sectional view illustrating the area A-B is described in more detail.

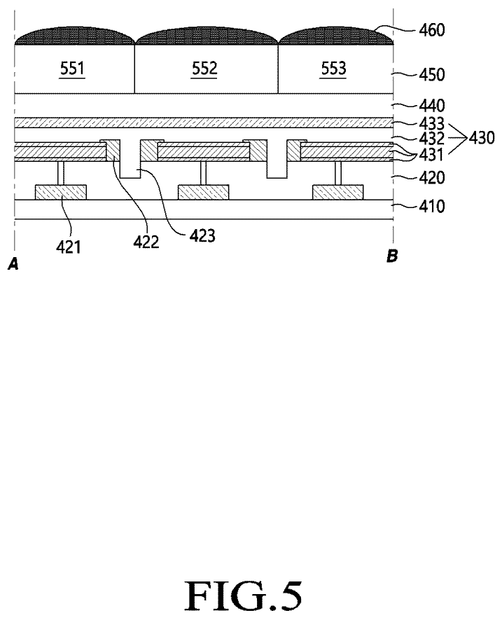

FIG. 5 is an example cross-sectional view taken along area A-B of FIG. 3.

Referring to FIG. 5, the substrate 410 may be disposed at the lowermost portion of the display panel 110.

Referring to FIG. 5, a transistor layer 420 may be disposed on a substrate 410. The transistor layer 420 may include a subpixel circuit 421. The subpixel circuit 421 may be electrically connected to the anode electrode layer through a contact hole formed in the transistor layer 420.

The transistor layer 420 may include a portion formed of an insulating material. Referring to FIG. 5, the outer portion of the subpixel circuit 421 may be a portion formed of an insulating material.

Referring to FIG. 5, the light emitting element layer 430 may be disposed on the transistor layer 420. The light emitting element layer 430 may include an anode electrode layer 431, a light emitting layer 432, and a cathode electrode layer 433.

The anode electrode layer 431 may be disposed on the transistor layer 420. The anode electrode layer 431 may be electrically connected to the subpixel circuit 421 through a contact hole formed in the transistor layer 420. The anode electrode layer 431 may be formed of a single metal material, or may also be formed of a plurality of metal materials. For example, the anode electrode layer 431 may be a transparent metal material such as ITO. Further, the anode electrode layer 431 may be a multilayer metal material such as Ti/Al/Ti. Referring to FIG. 5, the anode electrode layer 431 is illustrated as a multilayer metal material.

One anode electrode layer 431 may include a plurality of anode electrodes. Referring to FIG. 5, three anode electrodes are illustrated. One anode electrode may be surrounded by a bank 422. The bank 422 may define an emission area. The bank 422 may also be referred to as a fence.

Referring to FIG. 5, a trench 423 may be positioned between two anode electrodes. The trench 423 may be formed by etching the bank 422 disposed in the light emitting element layer 430 and the insulating material disposed in the transistor layer 420. When the trench 423 is positioned between the two anode electrodes, side current leakage may be prevented.

The light emitting layer 432 may be disposed on the anode electrode layer 431. The light emitting layer 432 may emit white light, and may be referred to as a WOLED. The cathode electrode layer 433 may be disposed on the light emitting layer 432. The cathode electrode layer 433 may be referred to as a cathode electrode for convenience. The anode electrode, the light emitting layer 432, and the cathode electrode may constitute one light emitting element ED.

The encapsulation layer 440 may be disposed on the cathode electrode layer 433. The encapsulation layer 440 may protect the light emitting element layer 430 from the outside.

The color filter layer 450 may be disposed on an encapsulation layer upper surface 444US of the encapsulation layer 440, and the micro-lens array 460 may be disposed on the color filter layer 450. The micro-lens array 460 may include a plurality of lenses, and each of the plurality of lenses may be disposed to correspond to the position of one color filter.

The color filter layer 450 may include a plurality of color filters 551, 552, and 553. The plurality of color filters 551, 552, and 553 may include a red color filter R, a green color filter G, and a blue color filter B. The plurality of color filters 551, 552, and 553 may be sequentially formed for each specific color. For example, the plurality of color filters 551, 552, and 553 may be formed in the order of a red color filter R, a green color filter G, and a blue color filter B.

Meanwhile, after the red color filter R is formed, the green color filter G may be formed. When the green color filter G is made, the completed red color filter R may be damaged. Further, when the blue color filter B is made, the completed red color filter R and green color filter G may be damaged. For example, as the completed color filters 551, 552, and 553 are exposed to the developing process multiple times, the color filter may be damaged. When a portion of the color filter is damaged, light leakage may occur. Further, the micro-lens array 460 should be placed on the flat color filter layer 450, and if the color filter is damaged, the micro-lens array 460 may not be placed flat.

In particular, in the case of an OLEDOS in which the substrate 410 is a silicon substrate, as fine processing is performed, the overall performance of the panel may deteriorate even when the flattening of the color filter layer becomes a little. Further, in the case of an OLEDOS, since high-temperature processing is impossible, low-temperature processing may be performed multiple times. In this case, as low-temperature processing is performed multiple times, the color filter may be more prone to damage. The above-described process may be, e.g., a hard bake process, and the hard bake process may be performed after the development process.

Embodiments of the disclosure may provide a display device capable of protecting a color filter layer 450 through a protective layer.

Embodiments of the disclosure may provide a display device capable of placing a color filter layer 450 flat through a protective layer.

Embodiments of the disclosure may provide a display device capable of placing a micro-lens array 460 flat through a protective layer.

Embodiments of the disclosure may provide a display device capable of low power consumption by increasing power efficiency by placing a color filter layer 450 and a micro-lens array 460 flat. A detailed description thereof is given below.

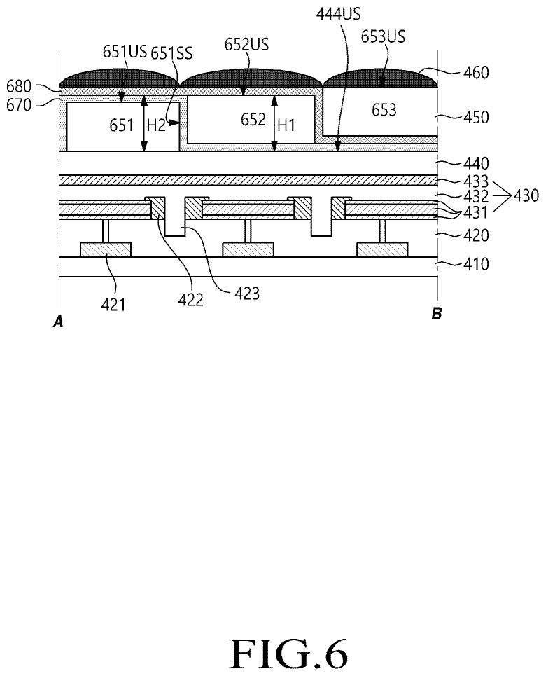

FIG. 6 is an example cross-sectional view taken along area A-B of FIG. 3.

Among the components of the display panel 110 illustrated in FIG. 6, descriptions of the same components as those of the display panel 110 illustrated in FIG. 5 may be omitted.

Referring to FIG. 6, a color filter layer 450 may be disposed on an encapsulation layer 440. The color filter layer 450 may include a first color filter 651, a second color filter 652, and a third color filter 653.

The first color filter 651 may be disposed on the encapsulation layer 440. The first color filter 651 may be a color filter for implementing a first color. For example, the first color may be red.

The first protective layer 670 may be disposed to cover the first color filter 651. The first protective layer 670 may extend from an upper surface 651US of the first color filter 651 toward a side surface 651SS of the first color filter 651. The first protective layer 670 may descend along the side surface 651SS of the first color filter 651, and the extended first protective layer 670 may contact the encapsulation layer 440. The first protective layer 670 in contact with the first color filter 651 may extend in contact with the encapsulation layer 440.

Referring to FIG. 6, the first protective layer 670 is positioned on the left side surface and the right side surface of the first color filter 651. Further, the first protective layer 670 may extend from the upper surface 651US of the first color filter 651 down the right side surface 651SS of the first color filter 651.

The first protective layer 670 may include a transparent material. The first protective layer 670 may have a transparent property, and thus light may easily pass through the first protective layer 670.

The first protective layer 670 may be a non-conductive metal oxide. For example, it may be Al₂O₃ (aluminum oxide), SiO₂ (silicon oxide), TiO₂ (titanium oxide), ZrO₂ (zirconium oxide), HfO₂ (hafnium oxide), MgO (magnesium oxide), CaO (calcium oxide), SnO₂ (tin oxide), and La₂O₃ (lanthanum oxide).

After the first protective layer 670 is formed, a second color filter 652 may be formed. The second color filter 652 may be positioned on the encapsulation layer 440. The second color filter 652 may be disposed outside the first color filter 651. The second color filter 652 may be positioned adjacent to the first color filter 651.

The second color filter 652 may be a color filter for implementing a second color. For example, the second color may be green.

The height H1 of the upper surface of the second color filter 652 may be the same as the height H2 of the upper surface of the first protective layer 670 overlapping the first color filter 651.

Since the first color filter 651 is covered by the first protective layer 670, the first color filter 651 may not be damaged when the second color filter 652 is formed.

The second protective layer 680 may be disposed to cover the second color filter 652. The second protective layer 680 may extend from the upper surface of the second color filter 652 to the side surface of the second color filter 652.

The second protective layer 680 may be disposed on the first color filter 651. The second protective layer 680 may be disposed in contact with the first protective layer 670 overlapping the first color filter 651. The second protective layer 680 may extend from an upper surface of the first protective layer 670 overlapping the first color filter 651 to an upper portion of the second color filter 652.

The second protective layer 680 may extend from the upper surface of the second color filter 652 toward the side surface of the second color filter 652. The second protective layer 680 may extend below the side surface of the second color filter 652, and the second protective layer 680 may be disposed in contact with the first protective layer 670.

The first protective layer 670 may pass through the lower portion of the second color filter 652 and extend. The first protective layer 670 may be positioned between the second color filter 652 and the encapsulation layer 440.

The first protective layer 670 may be positioned between the side surface of the first color filter 651 and the side surface of the second color filter 652.

After the second protective layer 680 is formed, a third color filter 653 may be formed. The third color filter 653 may be positioned on the encapsulation layer 440. The third color filter 653 may be disposed outside the second color filter 652. The third color filter 653 may be positioned adjacent to the second color filter 652.

The third color filter 653 may be a color filter for implementing a third color. For example, the third color may be blue.

The height of the upper surface of the third color filter 653 may be the same as the height of the upper surface of the second protective layer 680 overlapping the second color filter 652.

As the second color filter 652 is covered by the second protective layer 680, the second color filter 652 may not be damaged when the third color filter 653 is formed. Further, as the first color filter 651 is covered by the first protective layer 670, the first color filter 651 may not be damaged when the third color filter 653 is formed.

The second protective layer 680 may pass through the lower portion of the third color filter 653 and extend. The second protective layer 680 may be positioned between the third color filter 653 and the encapsulation layer 440.

The second protective layer 680 may be positioned between the side surface of the second color filter 652 and the side surface of the third color filter 653.

Like the first protective layer 670, the second protective layer 680 may include a transparent material. Like the first protective layer 670, the second protective layer 680 may be a non-conductive metal oxide.

The first protective layer 670 may be positioned under the second color filter 652, and the first protective layer 670 and the second protective layer 680 may be positioned under the third color filter 653. Accordingly, the heights between the color filters 651, 652, and 653 may be slightly different.

Referring to FIG. 6, the height of the upper surface of the second color filter 652 may be higher than the height of the upper surface of the first color filter 651. The height of the upper surface of the third color filter 653 may be higher than the height of the upper surface of the first color filter 651. The height of the upper surface of the third color filter 653 may be higher than the height of the upper surface of the second color filter 652.

Referring to FIG. 6, the height of the lower surface of the second color filter 652 may be higher than the height of the lower surface of the first color filter 651. The height of the lower surface of the third color filter 653 may be higher than the height of the lower surface of the first color filter 651. The height of the lower surface of the third color filter 653 may be higher than the height of the lower surface of the second color filter 652.

The micro-lens array 460 may be disposed on the second protective layer 680. The micro-lens array 460 may include a plurality of lenses, and the plurality of lenses may be convex lenses.

Referring to FIG. 6, a portion of the micro-lens array 460 may be disposed on the second protective layer 680. For example, one convex lens may overlap the first color filter 651. Further, another convex lens may overlap the second color filter 652.

Referring to FIG. 6, a portion of the micro-lens array 460 may be positioned on the third color filter 653.

The micro-lens array 460 may include a plurality of convex lenses. As each of the plurality of lenses overlaps one color filter 651, 652, and 653, light extraction of light may be further enhanced.

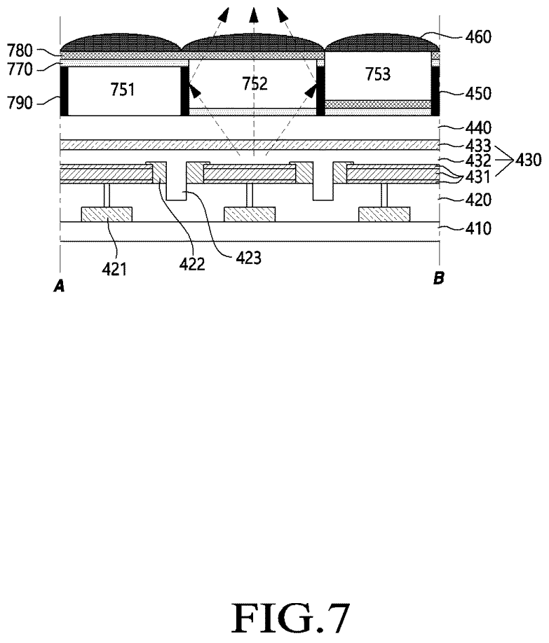

FIG. 7 is an example cross-sectional view taken along area A-B of FIG. 3.

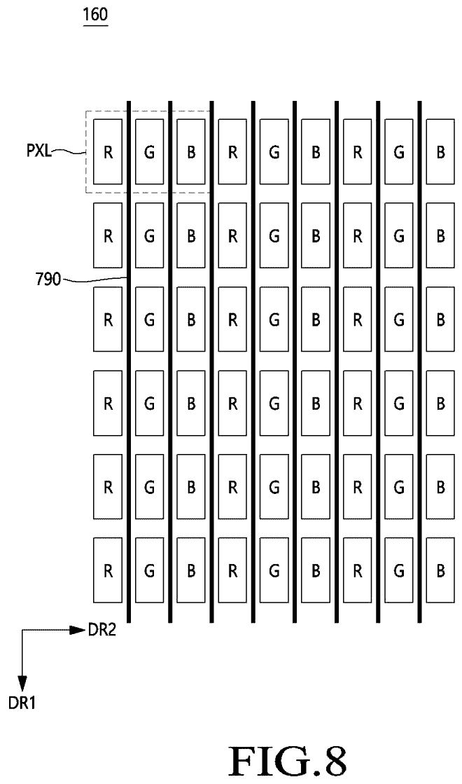

FIG. 8 is a plan view illustrating a plurality of subpixels SP according to embodiments of the disclosure.

Referring to FIG. 7, a plurality of partition walls 790 may be disposed on the encapsulation layer 440. Referring to FIG. 7, the height of the plurality of partition walls 790 may be the same as the height of the color filter.

Referring to FIG. 8, the color filters 751, 752, and 753 may be disposed in a line in the first direction DR1. Further, the plurality of partition walls 790 may extend in the first direction DR1. In other words, each of the plurality of partition walls 790 may have a shape of a long wall.

Referring to FIG. 8, a color filter may be positioned between two partition walls.

Referring to FIG. 7, color filters 751, 752, and 753 may be formed after the plurality of partition walls 790 are formed. The color filter may be disposed between every pair of partition walls of the plurality of partition walls 790. Referring to FIG. 7, it may be identified that each of the first color filter 751, the second color filter 752, and the third color filter 753 is disposed between the partition walls 790.

Referring to FIG. 7, the first protective layer 770 may be formed after the first color filter 751 is formed. The first protective layer 770 may be deposited on the entire surface, and the first protective layer 770 may be disposed to cover the plurality of partition walls 790. In this case, the first protective layer 770 may cover all of the surfaces of the plurality of partition walls 790, but the first protective layer 770 may not cover the corners of the plurality of partition walls 790.

Referring to FIG. 7, a portion of the first protective layer 770 may be disposed on the partition wall 790 contacting the first color filter 751. A portion of the first protective layer 770 may be disposed on an upper portion of each of the plurality of partition walls 790.

Referring to FIG. 7, a portion of the first protective layer 770 may be disposed under the second color filter 752. In this case, a portion of the first protective layer 770 may be disposed in contact with a side surface of the partition wall 790. However, the first protective layer 770 may be disposed to be spaced apart from the side surface of the partition wall 790.

After the first protective layer 770 is formed, a second color filter 752 may be formed. When the second color filter 752 is formed, the first color filter 751 is surrounded by the first protective layer 770 and the partition wall. In this case, when the second color filter 752 is formed, the first color filter 751 may not be damaged.

After the second color filter 752 is formed, a second protective layer 780 may be formed. The second protective layer 780 may be entirely deposited to cover the second color filter 752.

The second protective layer 780 may extend from the upper portion of the first color filter 751 to the upper portion of the second color filter 752. The second protective layer 780 may overlap the second color filter 752. A portion of the second color filter 752 may overlap the plurality of partition walls 790 and the first protective layer 770.

Referring to FIG. 7, a third color filter 753 may be formed after the second protective layer 780 is formed.

Referring to FIG. 7, the second protective layer 780 may be positioned between the third color filter 753 and the first protective layer 770.

When the third color filter 753 is formed, the second color filter 752 is surrounded by the second protective layer 780 and the partition wall 790. In this case, when the third color filter 753 is formed, the second color filter 752 may not be damaged. Further, when the third color filter 753 is formed, the first color filter 751 is surrounded by the first protective layer 770, the second protective layer 780, and the partition wall. In this case, when the third color filter 753 is formed, the first color filter 751 may not be damaged.

The plurality of partition walls 790 may include a metal material. For example, it may include silver (Ag), aluminum (Al), gold (Au), platinum (Pt), palladium (Pd), copper (Cu), nickel (Ni), chromium (Cr), titanium (Ti), zinc (Zn), molybdenum (Mo), tungsten (W), or the like.

The plurality of partition walls 790 may reflect light. Referring to FIG. 7, light incident on the plurality of partition walls 790 may be reflected and travel. Accordingly, the light emitted from the light emitting element ED may travel more intensively to the center of the lens by the partition wall 790 as well as the lens of the micro-lens array 460.

Embodiments of the disclosure described above are briefly described below.

Embodiments of the disclosure may provide a display device comprising a substrate, a light emitting element layer disposed on the substrate, an encapsulation layer disposed on the light emitting element layer, a first color filter disposed on the encapsulation layer, and a first protective layer extending from a first color filter upper surface of the first color filter to a first color filter side surface of the first color filter and extending from the first color filter side surface to an encapsulation layer upper surface of the encapsulation layer.

The display device may further comprise a second color filter positioned outside the first color filter side surface and positioned on the encapsulation layer. The first protective layer may pass through a lower portion of the second color filter.

A position of an upper surface of the first protective layer positioned on the first color filter upper surface may be the same as a position of an upper surface of the second color filter.

A position of an upper surface of the second color filter may be higher than a position of the first color filter upper surface.

The first protective layer may have a form of a thin film. The first protective layer may be thinner than the first color filter.

The first protective layer may include a transparent material.

The first protective layer may be a non-conductive metal oxide film.

The first protective layer may be disposed to cover the first color filter.

The display device may further comprise a second color filter positioned outside the first color filter side surface and formed after the first protective layer covering the first color filter is formed.

The display device may further comprise a second protective layer positioned on a second color filter upper surface of the second color filter. The second protective layer may extend from the second color filter upper surface to a position where the first protective layer overlaps the first color filter. The second protective layer may extend from the second color filter upper surface to a second color filter side surface of the second color filter and extend from the second color filter side surface to below the second color filter to contact the first protective layer.

The second protective layer may be disposed to cover the second color filter.

The display device may further comprise a third color filter positioned outside the second color filter side surface and formed after the second protective layer covering the second color filter is formed.

The second protective layer may contact the first protective layer on the third color filter upper surface of the third color filter.

The second protective layer may be positioned to be spaced apart from the first protective layer at a position where the second protective layer overlaps the second color filter.

The second protective layer may contacts the first protective layer on the first color filter upper surface.

The substrate may include a silicone material.

The display device may further comprise a micro-lens array including a plurality of convex lenses and positioned on the second protective layer. One convex lens among the plurality of convex lenses may be disposed on the first color filter.

The respective bottom surfaces of the plurality of convex lenses may be positioned at the same height.

The display device may further comprise at least two partition walls positioned on a side surface of the first color filter and including a metal material. Light incident on the at least two partition walls may be reflected from the plurality of partition walls.

Embodiments of the disclosure may provide a display device comprising a substrate, a light emitting element layer disposed on the substrate, an encapsulation layer disposed on the light emitting element layer, a plurality of partition walls disposed on the encapsulation layer and extending in a first direction, a first color filter disposed on the encapsulation layer and positioned between at least two of the plurality of partition walls, and a first protective layer covering an upper surface of the first color filter, wherein a side surface of the first color filter is disposed to contact the plurality of partition walls or the first protective layer, and wherein the plurality of partition walls include a material included in the first protective layer.

The above-described embodiments are merely examples, and it will be appreciated by one of ordinary skill in the art various changes may be made thereto without departing from the scope of the disclosure. Accordingly, the embodiments set forth herein are provided for illustrative purposes, but not to limit the scope of the disclosure, and should be appreciated that the scope of the disclosure is not limited by the embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate;
a light emitting element layer on the substrate;
an encapsulation layer on the light emitting element layer, the encapsulation layer having an encapsulation layer upper surface;
a first color filter on the encapsulation layer, the first color filter having a first color filter upper surface and a first color filter side surface; and
a first protective layer extending from the first color filter upper surface of the first color filter to the first color filter side surface of the first color filter and extending from the first color filter side surface to the encapsulation layer upper surface of the encapsulation layer.

2. The display device of claim 1, further comprising a second color filter positioned outside the first color filter side surface and positioned on the encapsulation layer,
wherein the first protective layer passes through a lower portion of the second color filter.

3. The display device of claim 2, wherein a position of an upper surface of the first protective layer positioned on the first color filter upper surface is the same as a position of an upper surface of the second color filter.

4. The display device of claim 2, wherein a position of an upper surface of the second color filter is higher than a position of the first color filter upper surface.

5. The display device of claim 1, wherein the first protective layer has a form of a thin film, and
wherein the first protective layer is thinner than the first color filter.

6. The display device of claim 1, wherein the first protective layer includes a transparent material.

7. The display device of claim 1, wherein the first protective layer is a non-conductive metal oxide film.

8. The display device of claim 1, wherein the first protective layer covers the first color filter.

9. The display device of claim 2, further comprising a second protective layer on a second color filter upper surface of the second color filter,
wherein the second protective layer extends from the second color filter upper surface to a position where the first protective layer overlaps the first color filter, and
wherein the second protective layer extends from the second color filter upper surface to a second color filter side surface of the second color filter and extends from the second color filter side surface to below the second color filter to contact the first protective layer.

10. The display device of claim 9, wherein the second protective layer covers the second color filter.

11. The display device of claim 10, further comprising a third color filter positioned outside the second color filter side surface.

12. The display device of claim 9, wherein the second protective layer is spaced apart from the first protective layer at a position where the second protective layer overlaps the second color filter.

13. The display device of claim 9, wherein the second protective layer contacts the first protective layer on the first color filter upper surface.

14. The display device of claim 9, further comprising a micro-lens array including a plurality of convex lenses,
wherein a portion of the micro-lens array is on the second protective layer, and another portion of the micro-lens array, different from the portion, is on a third color filter different from the second color filter.

15. The display device of claim 14, wherein respective bottom surfaces of the plurality of convex lenses are positioned at the same height.

16. The display device of claim 1, further comprising:
a first partition wall on one side of the first color filter and including a metal material; and
a second partition wall on an opposite side of the one side of the first color filter and including the metal material,
wherein light incident on the first partition wall and the second partition wall is reflected from the first partition wall and the second partition wall.

17. A display device, comprising:
a substrate;
a light emitting element layer on the substrate;
an encapsulation layer on the light emitting element layer;
a plurality of partition walls on the encapsulation layer and extending in a first direction;
a first color filter on the encapsulation layer and positioned between at least two of the plurality of partition walls; and
a first protective layer covering an upper surface of the first color filter,
wherein a side surface of the first color filter is disposed to contact the plurality of partition walls or the first protective layer, and
wherein the plurality of partition walls include a material included in the first protective layer.

18. The display device of claim 17, wherein the first protective layer is on the first color filter,
wherein the first protective layer is under the second color filter,
wherein a second protective layer extends from above the first color filter to the second color filter,
wherein the first protective layer and the second protective layer are under a third color filter, and
wherein the first protective layer and the second protective layer are not positioned on a side surface of the third color filter.
